(19) United States
(12) Patent Application Publication
(10) Pub. No.: US 2026/0293151 A1
(43) Pub. Date: Sep. 24, 2026

(54) MEMORY DEVICE

(71) Applicants: Kioxia Corporation, Tokyo (JP); SK hynix Inc., Icheon-si (KR)

(72) Inventors: Hyungjun CHO, Seongnam-si (KR); Kenichi YOSHINO, Seongnam-si (KR); Hyung-Woo AHN, Seongnam-si (KR); Takuya SHIMANO, Seoul (KR); Shin TAKANO, Seoul (KR); Jeongmyeong KIM, Icheon-si (KR)

(73) Assignees: Kioxia Corporation, Tokyo (JP); SK hynix Inc., Icheon-si (KR)

(21) Appl. No.: 19/321,511

(22) Filed: Sep. 8, 2025

(30) Foreign Application Priority Data
Mar. 18, 2025 (JP) 2025-043935

(51) Int. Cl. H10B 61/00; H10N 39/00; H10N 50/10; H10N 50/85

(52) U.S. Cl. CPC H10B 61/10; H10N 39/00; H10N 50/10; H10N 50/85

(57) ABSTRACT

According to one embodiment, a memory device includes: a switching element; and a variable resistance element, wherein the switching element includes: a first portion; and a second portion provided on a side face of the first portion, the first portion includes silicon (Si), a density of silicon in the first portion is higher than that of silicon oxide (SiO₂), and the second portion includes an element having a higher electronegativity than arsenic (As).

### CROSS-REFERENCE TO RELATED APPLICATIONS

This application is based upon and claims the benefit of priority from Japanese Patent Application No. 2025-043935, filed Mar. 18, 2025, the entire contents of which are incorporated herein by reference.

### FIELD

Embodiments described herein relate generally to a memory device.

### BACKGROUND

A memory device is known that stores data, using a variable resistance element configured to switch resistance. The variable resistance element is coupled in series with a switching element and functions as a memory cell.

### BRIEF DESCRIPTION OF THE DRAWINGS

FIG. 1 is a block diagram for illustrating the configuration of a memory device according to an embodiment.

FIG. 2 is a circuit diagram for illustrating the configuration of a memory cell array of the memory device according to the embodiment.

FIG. 3 is a plan view for illustrating the configuration of the memory cell array of the memory device according to the embodiment.

FIG. 4 is a cross-sectional view taken along line IV-IV of FIG. 3 and illustrates the cross-sectional structure of the memory cell array of the memory device according to the embodiment.

FIG. 5 is a cross-sectional view illustrating the configuration of a switching element of the memory device according to the embodiment.

FIG. 6 is a cross-sectional view illustrating the configuration of a magnetoresistive effect element of the memory device according to the embodiment.

FIG. 7 is a cross-sectional view for illustrating a first manufacturing method of a memory cell array used in the memory device according to the embodiment.

FIG. 8 is a cross-sectional view for illustrating the first manufacturing method of the memory cell array used in the memory device according to the embodiment.

FIG. 9 is a cross-sectional view for illustrating the first manufacturing method of the memory cell array used in the memory device according to the embodiment.

FIG. 10 is a cross-sectional view for illustrating the first manufacturing method of the memory cell array used in the memory device according to the embodiment.

FIG. 11 is a cross-sectional view for illustrating the first manufacturing method of the memory cell array used in the memory device according to the embodiment.

FIG. 12 is a cross-sectional view for illustrating the first manufacturing method of the memory cell array used in the memory device according to the embodiment.

FIG. 13 is a cross-sectional view for illustrating a second manufacturing method of a memory cell array used in the memory device according to the embodiment.

FIG. 14 is a cross-sectional view for illustrating the second manufacturing method of the memory cell array used in the memory device according to the embodiment.

### DETAILED DESCRIPTION

In general, according to one embodiment, a memory device includes: a switching element; and a variable resistance element, wherein the switching element includes: a first portion; and a second portion provided on a side face of the first portion, the first portion includes silicon (Si), a density of silicon in the first portion is higher than that of silicon oxide (SiO₂), and the second portion includes an element having a higher electronegativity than arsenic (As).

Embodiments will be described with reference to the accompanying drawings. In the descriptions below, structural elements having similar functions and configurations will be denoted by the same reference symbols. To distinguish a plurality of structural elements having common reference numerals, suffixes will be attached to the common reference numerals. If the structural elements do not have to be distinguished particularly, only the common reference numerals will be used, and no suffixes will be attached. The suffixes are not limited to subscripts and superscripts but include, for example, lower case English letters appended to the reference numerals, and indices or the like indicating arrangements.

### 1 Embodiment

The memory device 1 is a memory device that stores data using a variable resistance element. More specifically, the memory device 1 according to the embodiment is, for example, a magnetic memory device (MRAM: Magnetoresistive Random Access Memory) that uses a perpendicular magnetization method. In this device, an element having a magnetoresistance effect due to a magnetic tunnel junction (MTJ: Magnetic Tunnel Junction) is used as a variable resistance element. In the description below, the variable resistance element will be simply referred to as an MTJ element. In the description below, reference will be made to a case in which the memory device 1 is a magnetic memory device including an MTJ element as a variable resistance element; however, this is merely an example and not intended to be limiting. The memory device 1 may include an element different from an MTJ element as the variable resistance element. For example, the memory device 1 may be a resistive random access memory (ReRAM) or a phase-change random access memory (PcRAM).

### 1.1 Configuration

The configuration of the memory device according to the embodiment will be described.

### 1.1.1 Overall Configuration

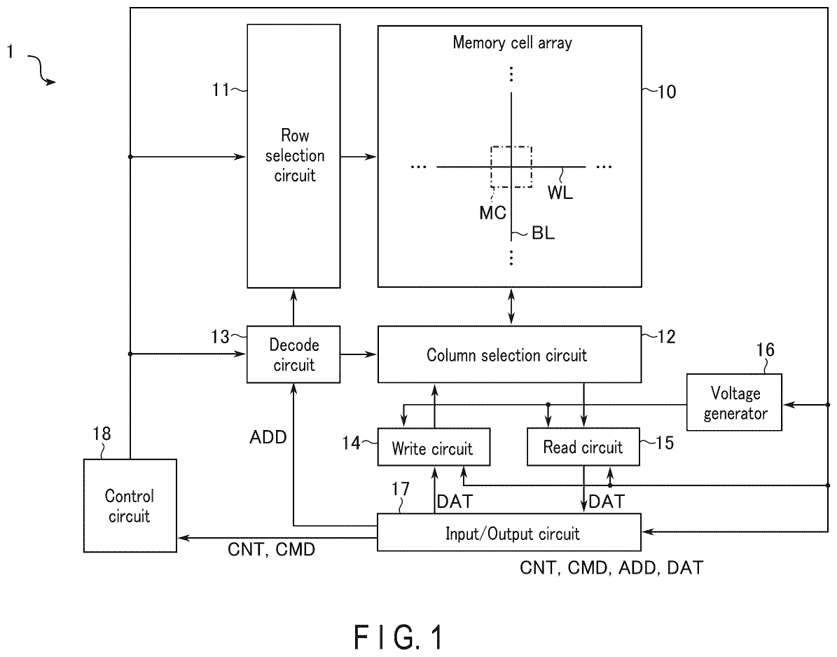

An example of the overall configuration of the memory device according to the embodiment will be described with reference to FIG. 1. FIG. 1 is a block diagram for illustrating the configuration of the memory device according to the embodiment.

As shown in FIG. 1, the memory device 1 includes a memory cell array 10, a row selection circuit 11, a column selection circuit 12, a decode circuit 13, a write circuit 14, a read circuit 15, a voltage generator 16, an input/output circuit 17, and a control circuit 18.

The memory cell array 10 includes a plurality of memory cells MC each associated with a set consisting of a row and a column. The memory cells MC in the same row are coupled to the same word line WL. The memory cells MC in the same column are coupled to the same bit line BL.

The row selection circuit 11 is coupled to the memory cell array 10 via a word line WL. A decode result (row address) of an address ADD from the decode circuit 13 is supplied to the row selection circuit 11. The row selection circuit 11 sets, in the selected state, the word line WL corresponding to the row based on the decoding result of the address ADD. In the description below, the word line WL set in the selected state will be referred to as a selected word line WL. The word lines WL other than the selected word line WL will be referred to as non-selected word lines WL.

The column selection circuit 12 is coupled to the memory cell array 10 via a bit line BL. A decode result (column address) of an address ADD from the decode circuit 13 is supplied to the column selection circuit 12. The column selection circuit 12 sets, in the selected state, the bit line BL corresponding to the row based on the decoding result of the address ADD. In the description below, the bit line BL set in the selected state will be referred to as a selected bit line BL. The bit lines BL other than the selected bit line BL will be referred to as non-selected bit lines BL.

The decode circuit 13 decodes an address ADD supplied from the input/output circuit 17. The decode circuit 13 supplies the decode result of the address ADD to both the row selection circuit 11 and the column selection circuit 12. The address ADD includes a selected column address and a row address.

The write circuit 14 writes data to a memory cell MC. The write circuit 14 includes, for example, a write driver (not shown).

The read circuit 15 reads data from the memory cell MC. The read circuit 15 includes, for example, a sense amplifier (not shown).

The voltage generator 16 generates voltages for various operations of the memory cell array 10 by using the power supply voltage provided from a device (not shown) external to the memory device 1. For example, the voltage generator 16 generates various voltages necessary for a write operation, and supplies the voltages to the write circuit 14. For example, the voltage generator 16 generates various voltages necessary for a read operation, and supplies the voltages to the read circuit 15.

The input/output circuit 17 performs communication with the outside of the memory device 1. The input/output circuit 17 transfers an address ADD supplied from outside the memory device 1 to the decode circuit 13. The input/output circuit 17 transfers a command CMD received from outside the memory device 1 to the control circuit 18. The input/output circuit 17 transmits and receives various control signals CNT between the outside of the memory device 1 and the control circuit 18. The input/output circuit 17 transfers data DAT received from outside the memory device 1 to the write circuit 14, and supplies the data DAT transferred from the read circuit 15 to the outside to the memory device 1.

Based on the control signal CNT and the command CMD, the control circuit 18 controls the operations of the row selection circuit 11, column selection circuit 12, decode circuit 13, write circuit 14, read circuit 15, voltage generator 16 and output circuit 17 that are included in the memory device 1.

### 1.1.2 Configuration of Memory Cell Array

### 1.1.2.1 Circuit Configuration of Memory Cell Array

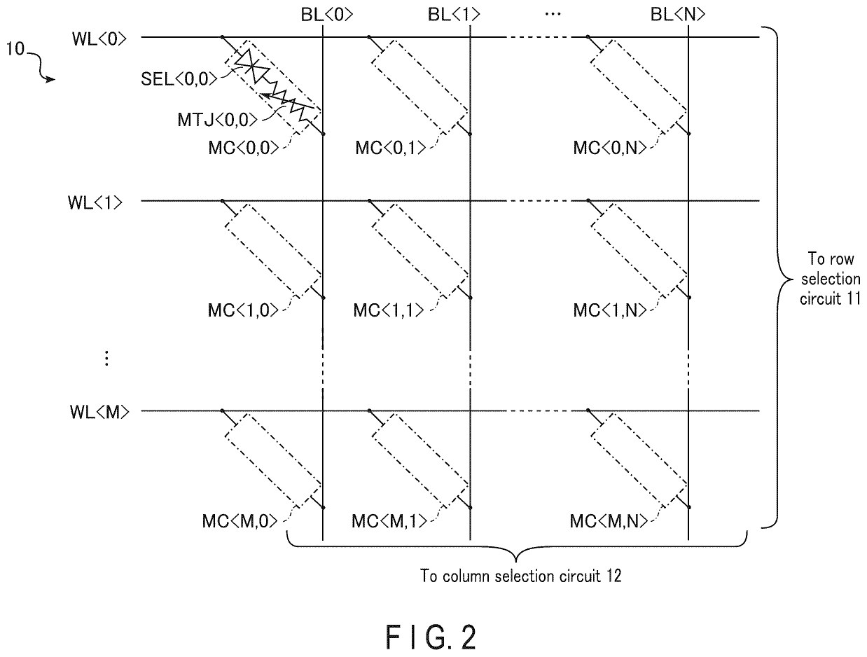

An example of the circuit configuration of the memory cell array 10 according to the embodiment will be described with reference to FIG. 2. FIG. 2 is a circuit diagram for illustrating the configuration of the memory cell array of the memory device according to the embodiment. In FIG. 2, the word lines WL are shown, classified by subscripts that include an index “<>.”

The memory cells MC are arranged in a matrix in the memory cell array 10, and are each associated with a set consisting of one of a plurality of bit lines BL (BL<0>, BL<1>, . . . , BL<N>) and one of a plurality of word lines WL (WL<0>, WL<1>, . . . , WL<M>) (M and N are natural numbers). That is, the memory cell MC<i, j> (0≤i≤M, 0≤j≤N, i and j are natural numbers) is coupled between the word line WL<i> and the bit line BL<j>.

The memory cell MC<i, j> includes a switching element SEL<i, j> and a magnetoresistive effect element MTJ<i, j>, which are coupled in series.

The switching element SEL is a two-terminal switching element. The two-terminal switching element differs from a three-terminal switching element such as a transistor in that it does not include a third terminal. The switching element SEL can be switched between a high-resistance state and a low-resistance state by a voltage applied across the two terminals. The high-resistance state is, for example, an off state in which the switching element is electrically non-conductive. The low-resistance state is, for example, an on state in which the switching element is electrically conductive. The switching element SEL switches between conductive and non-conductive states depending on the magnitude of the voltage applied to the corresponding memory cell MC, regardless of the polarity of the voltage applied across its two terminals (i.e., regardless of the direction of the current flow). Specific characteristics of the switching element SEL will be described later.

The magnetoresistive effect element MTJ can have its resistance state switched between a low-resistance state and a high-resistance state by a current controlled by the switching element SEL. The magnetoresistive effect element (MTJ) can write data by changing its resistance state, and thus functions as a memory element that retains the written data in a nonvolatile manner and allows the data to be read out.

### 1.1.2.2 Planar Structure of Memory Cell Array

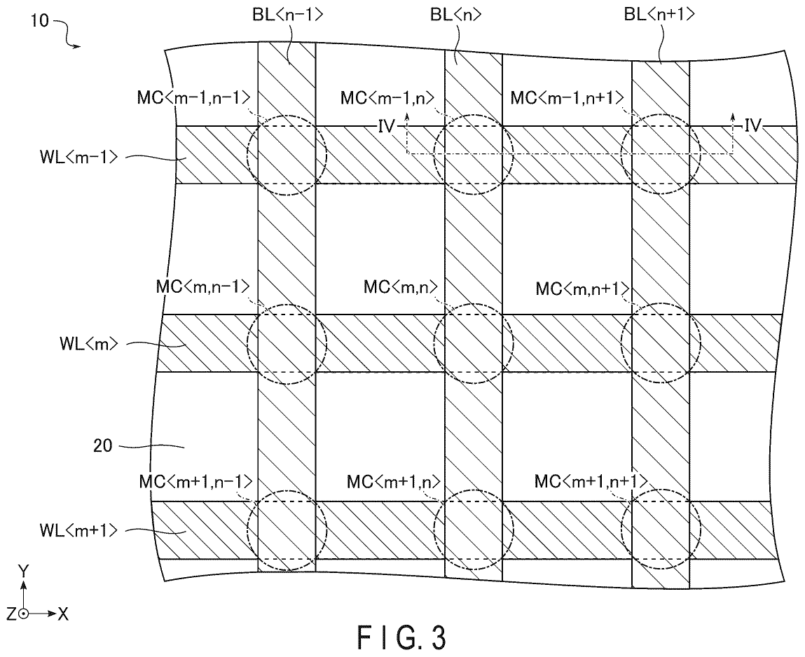

An example of the planar structure of the memory cell array 10 will be described with reference to FIG. 3. FIG. 3 is a plan view for illustrating the configuration of the memory cell array of the memory device according to the embodiment. FIG. 3 shows a plurality of memory cells MC provided between three word lines WL<m−1>, WL<m> and WL<m+1> and three bit lines BL<n−1>, BL<n> and BL<n+1> of the memory cell array 10 (1≤m≤M−1, 1≤n≤N−1). For convenience of description, an interlayer insulating film is omitted in FIG. 3.

The memory cell array 10 is provided, for example, above the semiconductor substrate 20. In the description below, a plane parallel to the surface of the semiconductor substrate 20 is defined as an XY plane, and a direction perpendicular to the XY plane is defined as a Z direction. In the XY plane, one of the two mutually perpendicular directions is defined as an X direction and the other as a Y direction.

The memory cells MC are provided between the word lines WL and the bit lines BL. In the example in FIG. 3, the word lines WL are shown below the memory cells MC, and the bit lines BL are shown above the memory cells MC, but this is not restrictive, and the vertical arrangement of the word lines WL and bit lines BL may be reversed.

Each of the plurality of memory cells MC has, for example, a circular shape when viewed from above.

The plurality of word lines WL are arranged along the Y direction. Each of the word lines WL extends along the X direction. The plurality of bit lines BL are arranged along the X direction. Each of the bit lines BL extends along the Y direction. One memory cell MC is provided at the intersection of one bit line BL and one word line WL.

### 1.1.2.3 Cross-Sectional Structure of Memory Cell Array

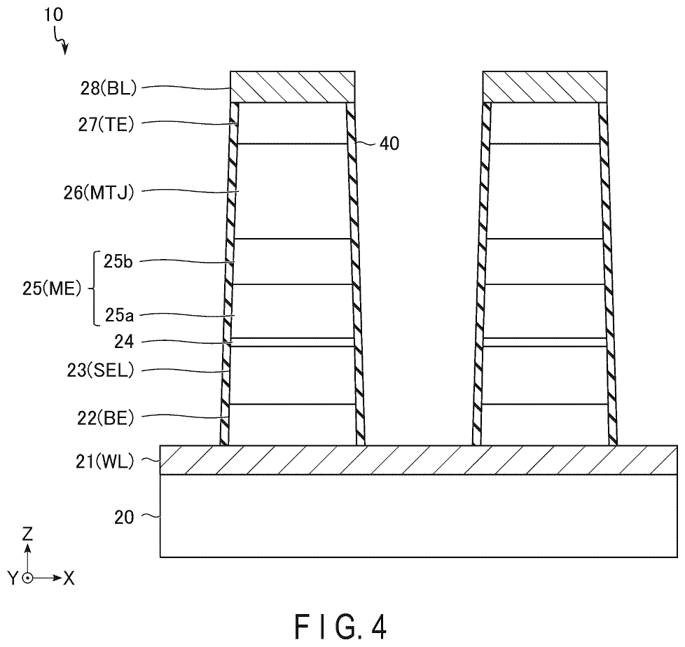

An example of the cross-sectional structure of the memory cell array 10 will be described with reference to FIG. 4. FIG. 4 is a cross-sectional view taken along line IV-IV in FIG. 3 and illustrates the cross-sectional structure of the memory cell array of the memory device according to the embodiment.

The memory cell array 10 includes a plurality of conductors 21, a plurality of electrodes 22, a plurality of elements 23, a plurality of conductors 24, a plurality of electrodes 25, a plurality of elements 26, a plurality of electrodes 27, and a plurality of conductors 28. Each electrode 25 includes electrodes 25a and 25b. Each of the conductors 21, 24 and 28, the electrodes 22, 25a, 25b and 27, and the elements 23 and 26 has a circular shape in the XY cross section in accordance with each memory cell MC having a circular shape when viewed from above.

The plurality of conductors 21 are provided, for example, on the upper face of the semiconductor substrate 20. Each of the conductors 21 extends in the X direction. As shown in FIG. 3, the plurality of conductors 21 are aligned along the Y direction in an area not shown in FIG. 4. Each of the plurality of conductors 21 has conductivity and functions as a word line WL. The plurality of conductors 21 are insulated from each other. With reference to FIG. 4, reference was made to the case where the plurality of conductors 21 are provided on the semiconductor substrate 20, but this is not restrictive. For example, a layer different from the plurality of conductors 21 and the semiconductor substrate 20 may be provided between them.

The plurality of electrodes 22 are provided on the upper face of each of the plurality of conductors 21. The plurality of electrodes 22 provided on the upper face of the same conductor 21 are aligned in the X direction. In FIG. 4, two electrodes 22 included among the plurality of electrodes 22 are shown, and these electrodes are provided on two conductors 21, respectively. Each of the plurality of electrodes 22 is used as a lower electrode BE.

On the upper face of each of the plurality of electrodes 22, one element 23, which is a corresponding one of the plurality of elements 23, is provided. Each of the plurality of the elements 23 is used as a switching element SEL. A more specific configuration of the plurality of elements 23 will be described later.

On the upper face of each of the plurality of elements 23, a corresponding one of the plurality of conductors 24 is provided. The conductor 24 includes, for example, at least one of a metal element or a metalloid element. More specifically, the conductor 24 includes, for example, at least one of aluminum (Al), titanium (Ti), titanium nitride (TiN), a compound (WSiN) of tungsten (W), silicon (Si) and nitrogen (N), chromium (Cr), iron (Fe), cobalt (Co), nickel (Ni), zinc (Zn), arsenic (As), platinum (Pt), gold (Au), and silver (Ag). Each of the plurality of conductors 24 functions as a conductive film.

On the upper face of each of the plurality pf conductors 24, a corresponding one of the plurality of electrodes 25a is provided. The plurality of electrodes 25a includes, for example, carbon (C).

On the upper face of each of the plurality of electrodes 25a, a corresponding one of the plurality of electrodes 25b is provided. The plurality of electrodes 25b include, for example, titanium nitride (TiN).

Each electrode 25 including the electrode 25a and the electrode 25b is used as a middle electrode ME.

On the upper face of each of the plurality of electrodes 25b, a corresponding one of the plurality of elements 26 is provided. Each of the plurality of elements 26 functions as a magnetoresistive effect element MTJ. Details of the configuration of the element 26 will be described later.

On the upper face of each of the plurality of elements 26, a corresponding one of the plurality of electrodes 27 is provided. Each of the plurality of electrodes 27 is used as a top electrode TE.

With the above configuration, a plurality of structures, each including the electrodes 22, 25, and 27, the conductor 24 and the elements 23 and 26, are also referred to as a plurality of stacked structures. Each of the plurality of stacked structures corresponds to one of the plurality of memory cells MC.

A sidewall insulator 40 is provided on the sidewall of each of the plurality of stacked structures in such a manner as to cover the sidewall. The sidewall insulator 40 is provided, for example, up to the same height as the upper face of the electrode 27. The sidewall insulator 40 may be made of a plurality of insulating materials.

The plurality of conductors 28 are aligned along the X direction. Although not shown, each of the plurality of conductors 28 extends along the Y direction in such manner as to come into contact with the upper face of each of the plurality of electrodes 27 aligned in the Y direction. Each of the plurality of conductors 28 is conductive and functions as a bit line BL.

### 1.1.2.4 Cross-Sectional Structure of Switching Element

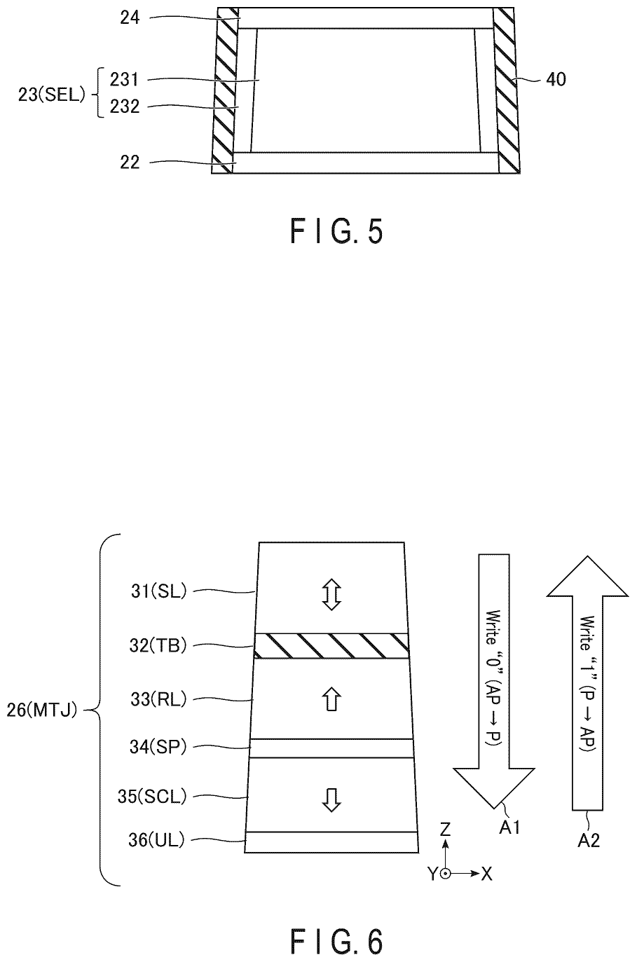

An example of the cross-sectional structure of the switching element SEL will be described with reference to FIG. 5. FIG. 5 is a cross-sectional view for illustrating the configuration of a switching element of the memory device according to the embodiment.

Each switching element SEL includes a first portion 231 and a second portion 232.

The lower face of the first portion 231 is provided on the upper face of the electrode 22 corresponding to the first portion 231. The upper face of the first portion 231 is in contact with the lower face of the conductor 24 corresponding to the first portion 231. The first portion 231 has, for example, a circular shape along the XY cross section.

The first portion 231 is formed of a material including silicon (Si) (i.e., a silicon (Si)-based material). The material includes, for example, at least one of silicon (Si), silicon nitride (SiN), silicon boride (SiB), silicon fluoride (SiF), and silicon tetrachloride (SiCl₄). The density (film density) of silicon (Si) in the first portion 231 is higher than that of silicon oxide (SiO₂), for example. The silicon oxide (SiO₂) mentioned in the above density comparison is, for example, silicon oxide (SiO₂) formed by CVD (Chemical Vapor Deposition). The material constituting the first portion 231 includes, for example, arsenic (As) injected by a process described below. The material constituting the first portion 231 includes, for example, either the metal elements or metalloid elements included in the conductor 24. For example, the material constituting the first portion 231 includes at least one of aluminum (Al), titanium (Ti), titanium nitride (TiN), a compound (WSiN) of tungsten (W), silicon (Si) and nitrogen (N), chromium (Cr), iron (Fe), cobalt (Co), nickel (Ni), zinc (Zn), arsenic (As), platinum (Pt), gold (Au), and silver (Ag), which are included in the conductor 24. The above elements are introduced into the first portion 231 by a process described below.

The material constituting the first portion 231 includes a chalcogenide material, for example. Specifically, the material constituting the first portion 231 may include at least one material selected from the group consisting of: hafnium oxide (HfO); a compound (AsHfO) of arsenic, hafnium, and oxygen; tantalum oxide (TaO); titanium oxide (TiO); tungsten oxide (WO); zirconium oxide (ZrO); aluminum oxide (AlO); nickel oxide (NiO); niobium oxide (NbO); a compound (AsSiOTi) of arsenic, silicon, oxygen, and titanium; a compound (AsSiO) of arsenic, silicon, and oxygen; a compound (AsS) of arsenic and sulfur; a compound (ZnTe) of zinc and tellurium; a compound (AsZnTe) of arsenic, zinc, and tellurium; a compound (SiZnTe) of silicon, zinc, and tellurium; a compound (AsSiZnTe) of arsenic, silicon, zinc, and tellurium; germanium selenide (GeSe); a compound (GeAsSeTe) of germanium, arsenic, selenium, and tellurium; a compound (GeTe) of germanium and tellurium; a compound (CTe) of carbon and tellurium; a compound (SiAsTe) of silicon, arsenic, and tellurium; a compound (SiGeAsTe) of silicon, germanium, arsenic, and tellurium; a compound (GeAsTe) of germanium, arsenic, and tellurium; a compound (AsTe) of arsenic and tellurium; and a compound (SiGeAsSe) of silicon, germanium, arsenic, and selenium; alternatively, the material constituting the first portion 231 may include a compound comprising at least one element selected from carbon (C), nitrogen (N), indium (In), and boron (B), and at least one of the chalcogenides described above. In addition, the material constituting the first portion 231 may include at least one material selected from: a compound (GeAs) of arsenic and germanium; and a compound in which at least one element selected from carbon (C), nitrogen (N), indium (In), and boron (B) is combined with said compound. The material constituting the first portion 231 has, for example, an amorphous structure. The material constituting the first portion 231 preferably includes at least one element selected from the Group 5 elements and the Group 6 elements. If the material constituting the first portion 231 includes at least one element selected from the Group 5 elements and the Group 6 elements, the density of trap sites of the material can be increased and the width of the band gap can be widened.

The second portion 232 is provided on the side face of the first portion 231. Thus, the second portion 232 constitutes the side face of the element 23. The side face of the second portion 232 is covered with a sidewall insulator 40.

The second portion 232 is formed, for example, by passivation of the material constituting the first portion 231, as described later. The passivation refers to a process of exposing the material to a substance with high electronegativity, or of causing a radical reaction or an ion reaction using plasma. By the passivation process, the material constituting the second portion 232 may include, for example, the same elements and compounds as those included in the material constituting the first portion 231. In addition, as a result of the passivation process, the material includes, for example, an element having higher electronegativity than arsenic (As). More specifically, the material includes, for example, at least one of oxygen (O), nitrogen (N), a bond (ON) of oxygen (O) and nitrogen (N), and a bond (CH) of carbon (C) and hydrogen (H). The above material is, for example, a material obtained by oxidizing the material constituting the first portion 231.

### 1.1.2.5 Magnetoresistive Effect Element

Next, an example of the structure of the magnetoresistive effect element MTJ of the memory device 1 according to the embodiment will be described with reference to FIG. 6. FIG. 6 is a cross-sectional view showing the configuration of the magnetoresistive effect element of the memory device according to the embodiment.

The element 26 used as the magnetoresistive effect element MTJ includes a ferromagnetic body 31, a nonmagnetic body 32, a ferromagnetic body 33, a nonmagnetic body 34, a ferromagnetic body 35, and a nonmagnetic body 36.

The ferromagnetic body 31 is a conductive film having ferromagnetism. The ferromagnetic body 31 has an easy magnetization axis perpendicular to the film face (Z direction). The ferromagnetic body 31 includes iron (Fe). The ferromagnetic body 31 may further include at least one element selected from cobalt (Co) and nickel (Ni). The ferromagnetic body 31 may further include boron (B). More specifically, the ferromagnetic body 31 includes, for example, cobalt iron boron (CoFeB), iron boride (FeB), or cobalt boride (CoB). The ferromagnetic material 31 is used as a storage layer SL.

The nonmagnetic body 32 is located on the lower face of the ferromagnetic body 31. The nonmagnetic body 32 is an insulating film having nonmagnetic property. The nonmagnetic body 32 is used as a tunnel barrier layer TB. The nonmagnetic body 32 is provided between the ferromagnetic body 31 and the ferromagnetic body 33, and forms a magnetic tunnel junction together with the ferromagnetic body 31 and the ferromagnetic body 33. Furthermore, in a case where an initial amorphous layer, such as cobalt iron boron (CoFeB), is used as the ferromagnetic material 31 and the interface layer of the ferromagnetic body 33, the nonmagnetic body 32 functions as a seed material that becomes a nucleus for growing a crystalline film from the interface with the ferromagnetic material 31 during the crystallization process of the ferromagnetic material 31. Similarly, in a case where cobalt iron boron (CoFeB) is used as the interface layer of the ferromagnetic body 33, the nonmagnetic body 32 also functions as a seed material for the ferromagnetic body 33. Here, the initial amorphous layer refers to a layer that is amorphous immediately after film formation and crystallizes upon annealing. The nonmagnetic body 32 has a tetragonal or cubic crystal structure, with its film face oriented along the (001) plane. An example of an oxide used for the nonmagnetic body 32 is magnesium oxide (MgO). Magnesium oxide (MgO) has a NaCl structure. In a case where magnesium oxide (MgO) is used as the nonmagnetic body 32, the (001) interface of MgO matches that of cobalt iron boron (CoFeB). Accordingly, cobalt iron boron (CoFeB) undergoes crystal growth through annealing and forms a body-centered cubic structure oriented in the (001) direction.

The ferromagnetic body 33 is located on the lower face of the nonmagnetic body 32. The ferromagnetic body 33 is a conductive film having ferromagnetism. The ferromagnetic body 33 is used as a reference layer RL. The ferromagnetic body 33 has an easy magnetization axis perpendicular to the film face (Z direction). The magnetization direction of the ferromagnetic body 33 is fixed. In the example in FIG. 5, the magnetization direction of the ferromagnetic body 33 is a direction orientated from the ferromagnetic body 33 toward the ferromagnetic body 31. It should be noted that the phrase “the magnetization direction is fixed” means that the magnetization direction remains unchanged even under a torque large enough to reverse that of the ferromagnetic body 31. Typically, an interface layer is used for the ferromagnetic body 33. As the interface layer for the ferromagnetic body 33, an initial amorphous layer such as cobalt iron boron (CoFeB) is used. Furthermore, an auxiliary ferromagnetic layer is provided in contact with the face of a cobalt iron boron (CoFeB) layer opposite to the face that is in contact with the magnesium oxide (MgO) layer. The auxiliary ferromagnetic layer includes at least one alloy film selected, for example, from cobalt platinum (CoPt), cobalt nickel (CoNi), and cobalt palladium (CoPd). The auxiliary ferromagnetic layer is a stacked film such as a Co/Pt stacked film or a Co/Pd stacked film. The cobalt iron boron (CoFeB) layer, serving as an initial amorphous layer, is used in a stacked structure together with the above-mentioned CoPt, CoPd, Co/Pt stacked films, Co/Pd stacked films, etc. In this case, the interface layer of the ferromagnetic body 33, such as the above-mentioned CoFeB layer, is formed closer to the nonmagnetic material 32 with (001)-oriented MgO than the other layers.

The nonmagnetic body 34 is located on the lower face of the ferromagnetic body 33. The nonmagnetic body 34 is a conductive film having nonmagnetic property. The nonmagnetic body 34 is used as a spacer layer SP. The nonmagnetic body 34 is made of an element selected, for example, from ruthenium (Ru), osmium (Os), rhodium (Rh), iridium (Ir), vanadium (V), and chromium (Cr), or an alloy of these. The ferromagnetic body 35 is located on the lower face of the nonmagnetic body 34. The ferromagnetic body 35 is a conductive film having ferromagnetism. The ferromagnetic body 35 is used as a shift cancel layer SCL. The ferromagnetic body 35 has an easy magnetization axis perpendicular to the film face (Z direction). The magnetization direction of the ferromagnetic body 35 is fixed. In the example in FIG. 5, the magnetization direction of the ferromagnetic body 35 is a direction orientated from the ferromagnetic body 33 toward the ferromagnetic body 35. The ferromagnetic body 35 includes at least one kind of alloy layer selected, for example, from cobalt platinum (CoPt), cobalt nickel (CoNi), and cobalt palladium (CoPd). The ferromagnetic material 35 may also be a stacked film such as a Co/Pt stacked film or a Co/Pd stacked film.

The ferromagnetic body 33 and the ferromagnetic body 35 are anti-ferromagnetically coupled to each other by the nonmagnetic body 34. That is, the ferromagnetic body 33 and the ferromagnetic body 35 are coupled such that they have anti-parallel magnetization directions. This coupling structure among the ferromagnetic body 33, the nonmagnetic body 34, and the ferromagnetic body 35 is referred to as a SAF (Synthetic Anti-Ferromagnetic) structure. The SAF structure allows the ferromagnetic body 35 to cancel the effect which the leakage magnetic field of the ferromagnetic body 33 has on the change in the magnetization direction of the ferromagnetic body 31. Thus, the ferromagnetic body 35 can substantially reduce the leakage magnetic field of the ferromagnetic body 33.

The nonmagnetic body 36 is located on the lower face of the ferromagnetic body 35. The nonmagnetic body 36 is a conductive film having nonmagnetic property. The nonmagnetic body 36 is used as an under layer UL. The nonmagnetic body 38 includes at least one element selected from the group including, for example, zirconium (Zr), hafnium (Hf), tungsten (W), chromium (Cr), molybdenum (Mo), niobium (Nb), titanium (Ti), tantalum (Ta), vanadium (V), ruthenium (Ru), and platinum (Pt).

The magnetoresistive effect element MTJ can take either the low-resistance state or the high-resistance state, depending on whether the relative relationship between the magnetization direction of the storage layer SL and the magnetization direction of the reference layer RL is parallel or anti-parallel. In the embodiment, a write current is made to flow through such a magnetoresistive effect element MTJ to control the magnetization direction of the storage layer SL relative to the magnetization direction of the reference layer RL. Specifically, a write method is adopted which utilizes spin transfer torque generated by the current flowing through the magnetoresistive effect element MTJ.

In a case where a write current Ic0 of a certain magnitude is made to flow through the magnetoresistive effect element MTJ in the direction from the storage layer SL toward the reference layer RL, i.e., in the direction of arrow A1 in FIG. 5, the relationship between the magnetization directions of the storage layer SL and the reference layer RL becomes parallel. In this parallel state, the resistance value of the magnetoresistive effect element MTJ is lowest, and the magnetoresistive effect element MTJ is in the low-resistance state. This low-resistance state is referred to as a “P (parallel) state,” and is defined, for example, as a state of data “0.”

Furthermore, in a case where a write current Ic1 larger than the write current Ic0 is made to flow through the magnetoresistive effect element MTJ in the direction from the reference layer RL toward the storage layer SL, i.e., in the direction of arrow A2 in FIG. 5, the relationship between the magnetization directions of the storage layer SL and the reference layer RL becomes anti-parallel. In this anti-parallel state, the resistance value of the magnetoresistive effect element MTJ is highest, and the magnetoresistive effect element MTJ is in the high-resistance state. This high-resistance state is referred to as a “AP (Anti-Parallel) state,” and is defined, for example, as a state of data “1.”

It should be noted that the way in which data “1” and data “0” are defined is not limited to the above example. For example, the P state may be defined as data “1” and the AP state as data “0.”

### 1.2 Manufacturing Methods of Memory Cell Array

Next, manufacturing methods of the memory cell array 10 of the memory device 1 according to the embodiment will be described. In the description below, a first manufacturing method and a second manufacturing method will be described as the manufacturing methods of the memory cell array 10 of the memory device 1 according to the embodiment.

### 1.2.1 First Manufacturing Method

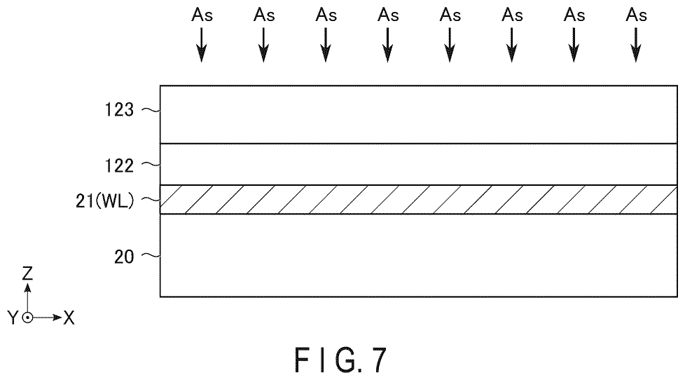

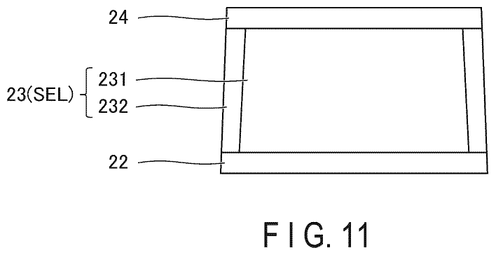

The first manufacturing method of the memory cell array 10 of the memory device 1 according to the embodiment will be described with reference to FIGS. 6, 7, 8, 9, 10, 11 and 12. FIGS. 7 to 12 are cross-sectional views for illustrating the first manufacturing method of the memory cell array of the memory device according to the embodiment. FIG. 7 to FIG. 10 and FIG. 12 correspond to the cross-sectional view shown in FIG. 4. FIG. 11 corresponds to the cross-sectional view shown in FIG. 5.

First, for example, a conductive layer 122 and an element layer 123 are formed above the semiconductor substrate 20 on which a plurality of conductors 21 are formed. The conductive layer 122 and the element layer 123 correspond to a plurality of electrodes 22 and a plurality of elements 23, respectively. Furthermore, as shown in FIG. 7, arsenic (As) is injected from above into the structure formed as described above. Thus, arsenic (As) is injected into the element layer 123. The material constituting the conductive layer 122 is similar to the material constituting the plurality of electrodes 22. After the injection of arsenic (As), the material forming the element layer 123 is similar to that forming the first portion 231, except that the elements present in a conductive layer 124 (described below) have not yet been introduced.

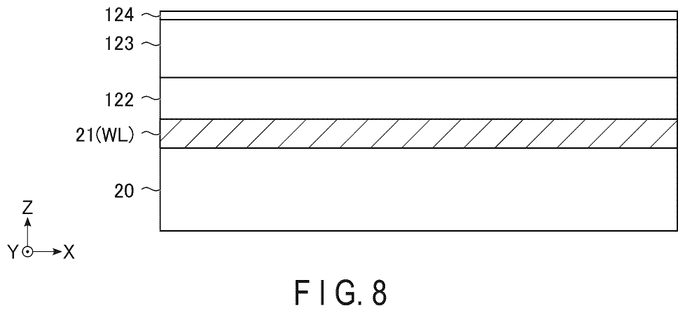

Then, as shown in FIG. 8, a conductive layer 124 is formed on the upper face of the element layer 123. The conductive layer 124 corresponds to the plurality of conductors 24. The material constituting the conductive layer 124 is similar to the material constituting the plurality of conductors 24.

Then, for example, a voltage application process is performed on the structure formed as described above. Thereby, at least one of the metal elements and metalloid elements included in the conductive layer 124 is introduced into the element layer 123. The material constituting the element layer 123 is made similar to the material constituting the first portion 231.

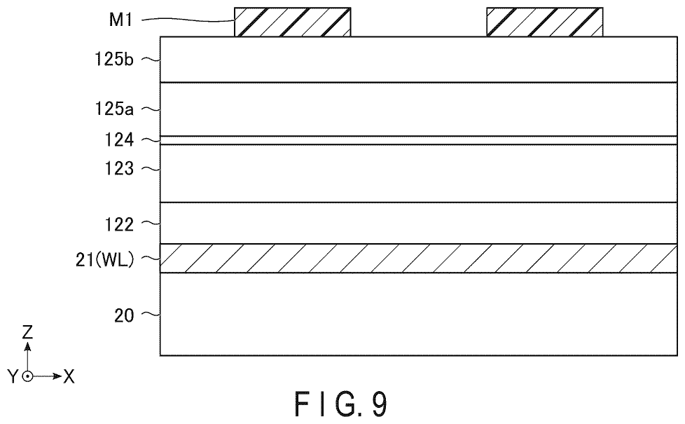

Then, conductive layers 125a and 125b are formed on the upper face of the conductive layer 124. The conductive layers 125a and 125b correspond to the plurality of electrodes 25a and 25b, respectively. The materials constituting the conductive layers 125a and 125b are similar to the materials constituting the plurality of electrodes 25a and 25b, respectively. The conductive layer 125a is formed by depositing a carbon film using PVD (Physical Vapor Deposition), for example. The conductive layer 125b is formed by depositing a titanium nitride (TiN) film using PVD, for example. Furthermore, as shown in FIG. 9, a plurality of masks M1 are formed on the conductive layer 125b. The plurality of masks M1 are provided, for example, as a plurality of cylindrical structures arranged in a matrix on the upper face of the conductive layer 125b, and each of the plurality of cylindrical structures protects an area corresponding to one memory cell MC.

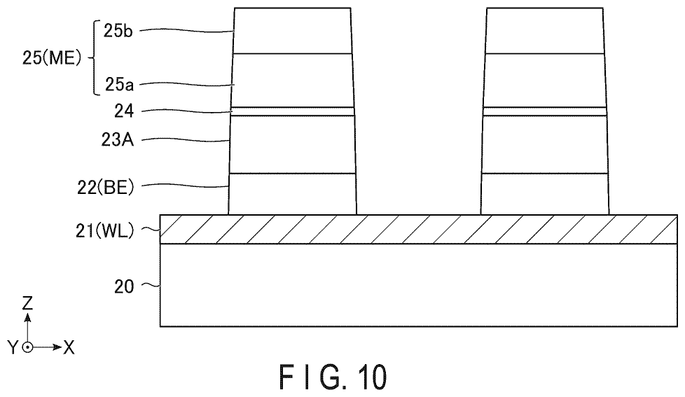

Then, the conductive layers 122, 124, 125a and 125b and the element layer 123 are etched by performing etching using the plurality of masks M1. Thus, those portions of the conductive layers 122, 124, 125a and 125b and the element layer 123 that are not protected by the plurality of masks M1 are removed. Furthermore, the conductor 21 located below the portions is exposed. The etching mentioned above is, for example, IBE (Ion Beam Etching) or RIE (Reactive Ion Etching). By the above etching, a plurality of structures are formed such that each includes the electrodes 22 and 25, the portions 23A corresponding to the element 23, and the conductor 24. Also, as shown in FIG. 10, the plurality of masks M1 are removed.

By performing passivation processing on the portion 23A in each of the structures formed as described above, the first portion 231 and the second portion 232 are formed as shown in FIG. 11. That is, a plurality of elements 23 are formed. The processing is, for example, processing in which the portion 23A is oxidized in an oxygen (O₂) atmosphere or an atmosphere including oxygen, such as an air atmosphere, or processing in which the portion 23A is made to react with generated oxygen radicals. Thus, the portion of the portion 23A that constitutes the side face is made into the second portion 232. The other portion is made into the first portion 231.

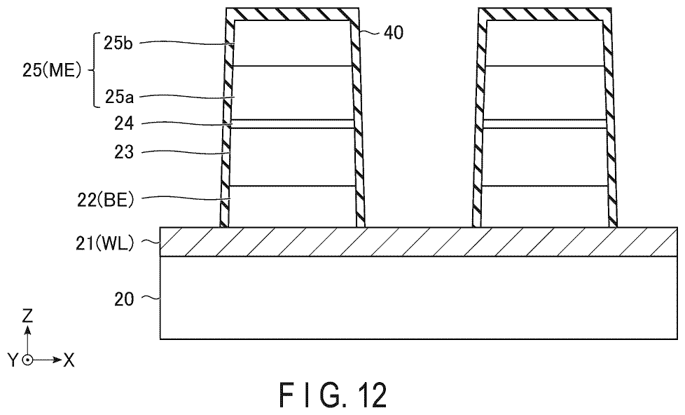

Then, as shown in FIG. 12, a sidewall insulator 40 is formed on the side and upper faces of the structures each including electrodes 22 and 25, element 23, and conductor 24.

Next, the portion of the sidewall insulator 40 formed on the upper face of each electrode 25b as described above is removed. Then, a plurality of elements 26, a plurality of electrodes 27, a plurality of conductors 28, and a portion of the sidewall insulator 40 included above the electrode 25 are formed.

In this manner, the configuration corresponding to the memory cell array 10 is formed.

### 1.2.2 Second Manufacturing Method

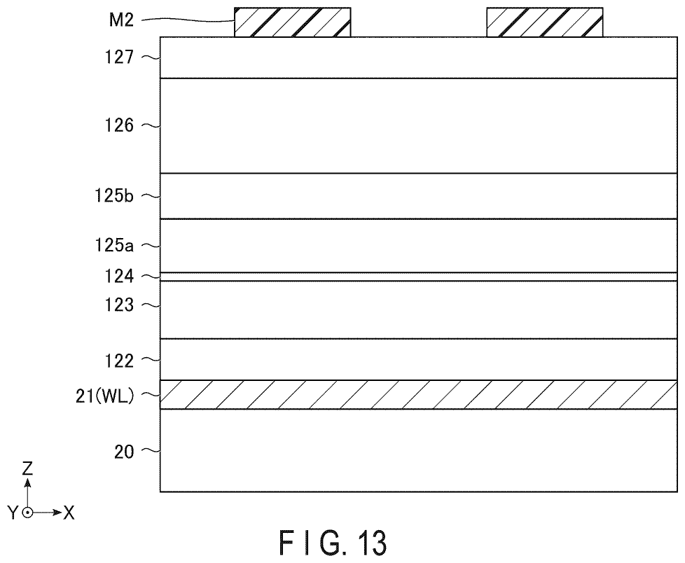

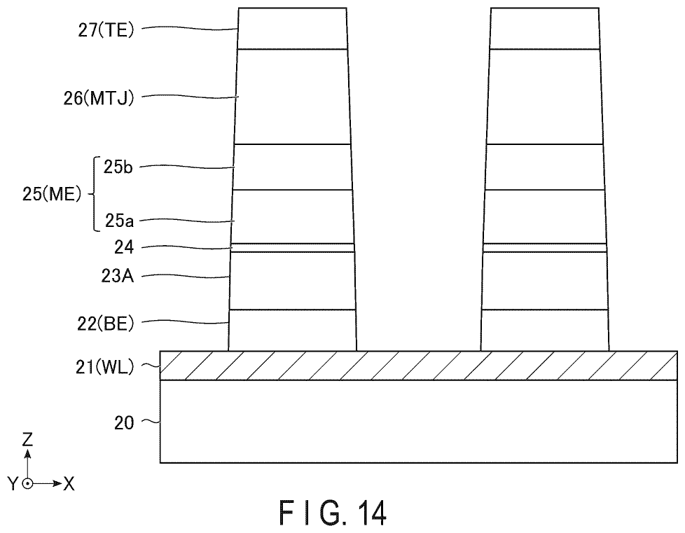

Next, the second manufacturing method of the memory cell array 10 of the memory device 1 according to the embodiment will be described with reference to FIG. 13 and FIG. 14. FIG. 13 and FIG. 14 are cross-sectional views for illustrating the second manufacturing method of the memory cell array of the memory device according to the embodiment. FIGS. 13 and 14 correspond to the cross-sectional view shown in FIG. 4. The second manufacturing method will be described below, focusing mainly on the differences from the first manufacturing method.

In the second manufacturing method, conductive layers 125a and 125b are formed in the same manner as in the first manufacturing method, and the element layer 126 and the conductive layer 127 are formed in this order on the conductive layer 125b without forming a plurality of masks M1. The element layer 126 and the conductive layer 127 correspond to the plurality of elements 26 and the plurality of electrodes 27, respectively. The element layer 126 is composed of a plurality of films, similarly to the elements 26. The material constituting the conductive layer 127 is similar to the material constituting the plurality of electrodes 27.

Furthermore, as shown in FIG. 13, a plurality of masks M2 are formed on the conductive layer 127. The plurality of masks M2 are provided, for example, as a plurality of cylindrical structures arranged in a matrix on the upper face of the conductive layer 127, and each of the plurality of cylindrical structures protects an area corresponding to one memory cell MC.

Then, the conductive layers 122, 124, 125a, 125b and 127 and the element layer 123 and 126 are etched by performing etching using the plurality of masks M2. Thus, those portions of the conductive layers 122, 124, 125a, 125b and 127 and element layers 123 and 126 that are not protected by the plurality of masks M2 are removed. In addition, the conductor 21 located below the portions is exposed. The above etching is, for example, IBE or RIE. By the above etching, a plurality of structures are formed such that each includes the electrodes 22, 25 and 27, the portion 23A corresponding to the element 23, the element 26, and the conductor 24. Also, as shown in FIG. 14, the plurality of masks M2 are removed.

Subsequently, the portion 23A is processed into a plurality of elements, using a process similar to that described with reference to FIG. 11 in connection with the first manufacturing method.

Then, a sidewall insulator 40 is formed on the sidewall of each structure including electrodes 22, 25 and 27, elements 23 and 26, and conductor 24. Also, a plurality of conductors 28 are formed.

In this manner, the configuration corresponding to the memory cell array 10 is formed.

### 1.3 Advantages of Embodiment

According to the embodiment, the characteristics of the memory device can be improved. The advantages of the embodiment will be described below.

The memory device 1 of the embodiment includes an element 23 functioning as a switching element SEL and a magnetoresistive effect element MTJ. The element 23 includes a first portion 231 and a second portion 232 provided on the side of the first portion 231. The first portion 231 includes silicon (Si). The density of the silicon (Si) in the first portion 231 is higher than that of the silicon oxide (SiO₂). The second portion 232 includes at least one of oxygen (O), nitrogen (N), a bond (ON) of oxygen (O) and nitrogen (N), and a bond (CH) of carbon (C) and hydrogen (H). With the above-mentioned configuration, deterioration of the characteristics of the switching element SEL can be suppressed. This enables improvement of the characteristics of the memory device 1.

The suppression of deterioration of the characteristics of the switching element SEL will be described in more detail.

As described above, the density of the silicon (Si) in the first portion 231 of the element 23 is higher than that of the silicon oxide (SiO₂). With this configuration, when arsenic (As) is injected into the element layer 123 during the process described with reference to FIG. 7 of the embodiment, the resulting damage can be suppressed compared with the case where arsenic is injected into an element layer composed of silicon oxide (SiO₂). More specifically, the generation of voids in the element can be suppressed. Thus, deterioration of the characteristics of the switching element SEL is suppressed.

As described above, the element 23 includes the inactivated second portion 232 provided on the side face of the first portion 231. The second portion 232 includes an element having a higher electronegativity than arsenic (As). With the above configuration, deterioration in the uniformity of the distribution of the injected arsenic (As) clusters can be suppressed. As a supplementary note, in a comparative example in which the surface of the element is not inactivated, the size of clusters formed within the element by the injected arsenic (As) may vary due to external influences. Thus, the uniformity in the size of the arsenic (As) clusters may decrease. The memory device performs a write operation and a read operation, for example, after a forming process is executed in which a switching element in its initial state is changed to an operational state. In the forming process, a conductive filament is formed in the switching element by increasing the voltage (forming voltage) applied across the terminals of the switching element SEL in the initial state and allowing a write current to flow. If a forming process is performed on a memory cell in which the uniformity in the size of arsenic (As) clusters has decreased, degradation in the characteristics of the switching element may occur, such as the element remaining constantly on. According to the embodiment, the second portion 232 can suppress a decrease in the uniformity of the distribution of arsenic (As) clusters. This suppresses the deterioration of the characteristics of the switching element SEL.

As a result of the above, deterioration of the characteristics of the switching element SEL can be suppressed.

The memory device 1 of the embodiment further includes a conductor 24 that functions as a conductive film. The first portion 231 contains at least one of the metal and metalloid elements included in the conductor 24, for example, by a voltage application process during the manufacturing process. With the above configuration, the conductivity of the first portion 231 can be improved. This enables suppression of an increase in the forming voltage. In addition, the operating speed of the switching element SEL can be improved.

### 2 Others

While certain embodiments have been described, these embodiments have been presented by way of example only and are not intended to limit the scope of the invention. Indeed, these embodiments can be implemented in various other forms; furthermore, various omissions, substitutions and changes in the form of the embodiments described herein may be made without departing from the spirit of the invention. The accompanying claims and their equivalents are intended to cover such forms or modifications as would fall within the scope and spirit of the invention.

1. A memory device comprising:
a switching element; and
a variable resistance element,
wherein the switching element includes:
a first portion; and
a second portion provided on a side face of the first portion,
the first portion includes silicon (Si),
a density of silicon in the first portion is higher than that of silicon oxide (SiO₂), and
the second portion includes an element having a higher electronegativity than arsenic (As).

2. The memory device according to claim 1, wherein the first portion includes at least one of silicon (Si), silicon nitride (SiN), silicon boride (SiB), silicon fluoride (SiF), and silicon tetrachloride (SiCl₄).

3. The memory device according to claim 1, wherein the second portion is made of a material identical to that of the first portion, but has been passivated.

4. The memory device according to claim 1, wherein the second portion includes at least one of oxygen (O), nitrogen (N), a bond (ON) of oxygen (O) and nitrogen (N), and a bond of carbon (C) and hydrogen (H).

5. The memory device according to claim 1, further comprising:
a conductive film provided between the switching element and the variable resistance element.

6. The memory device according to claim 5, wherein the conductive film and the switching element are in contact with each other.

7. The memory device according to claim 5, further comprising:
a first electrode provided between the conductive film and the variable resistance element,
wherein the conductive film is provided between the first electrode and the switching element.

8. The memory device according to claim 5, wherein the conductive film includes at least one of aluminum (Al), titanium (Ti), titanium nitride (TiN), a compound (WSiN) of tungsten (W), silicon (Si), and nitrogen (N), chromium (Cr), iron (Fe), cobalt (Co), nickel (Ni), zinc (Zn), arsenic (As), platinum (Pt), gold (Au), and silver (Ag).

9. The memory device according to claim 8, wherein the first portion includes at least one of aluminum (Al), titanium (Ti), titanium nitride (TiN), a compound (WSiN) of tungsten (W), silicon (Si), and nitrogen (N), chromium (Cr), iron (Fe), cobalt (Co), nickel (Ni), zinc (Zn), arsenic (As), platinum (Pt), gold (Au), and silver (Ag), which are included in the conductive film.

10. The memory device according to claim 1, wherein the density of silicon in the first portion is higher than the density of silicon oxide (SiO₂) formed by chemical vapor deposition.

11. The memory device according to claim 1, wherein the variable resistor element is provided on a side opposite to the substrate with respect to the switching element.

12. The memory device according to claim 1, wherein the variable resistance element includes:
a first ferromagnetic layer;
a second ferromagnetic layer;
a third ferromagnetic layer provided on a side opposite to the first ferromagnetic layer with respect to the second ferromagnetic layer;
a first nonmagnetic layer provided between the first ferromagnetic layer and the second ferromagnetic layer; and
a second nonmagnetic layer provided between the second ferromagnetic layer and the third ferromagnetic layer,
wherein the first nonmagnetic layer includes an oxide of magnesium (Mg).

13. The memory device according to claim 12, wherein the second nonmagnetic layer includes at least one element selected from the group including ruthenium (Ru), osmium (Os), rhodium (Rh), iridium (Ir), vanadium (V), and chromium (Cr).

14. The memory device according to claim 12, wherein the third ferromagnetic layer is provided between a substrate and the second ferromagnetic layer.

15. The memory device according to claim 12, wherein the second ferromagnetic layer and the third ferromagnetic layer are coupled to each other antiferromagnetically.

16. The memory device according to claim 1, wherein the switching element is a two-terminal switching element.

17. The memory device according to claim 1, wherein the variable resistance element is a magnetoresistive effect element.
